(19) United States
(12) Patent Application Publication
(10) Pub. No.: US 2025/0078946 A1
(43) Pub. Date: Mar. 6, 2025

(54) MEMORY DEVICE

(71) Applicant: Renesas Electronics Corporation, Tokyo (JP)

(72) Inventors: Tomohiro MIURA, Tokyo (JP); Kouji SATOU, Tokyo (JP); Shunya NAGATA, Tokyo (JP)

(21) Appl. No.: 18/806,844

(22) Filed: Aug. 16, 2024

(30) Foreign Application Priority Data
Aug. 30, 2023 (JP) 2023-139535

(51) Int. Cl. G11C 29/12; G11C 29/42

(52) U.S. Cl. CPC G11C 29/1201; G11C 29/12015; G11C 29/42

(57) ABSTRACT

Providing a memory device that initializes memory cell data in a batch by specifying initialization data, or a memory device that initializes memory cell data in a batch by partially masking the initialization area. A memory device is provided that includes a control circuit that receives an initialization mode signal transmitted from an initialization control circuit and generates an internal clock and a write control signal, an IO (Input/Output) input circuit that applies a Low level to the True side or Bar side of a bit line according to initialization data transmitted from the initialization control circuit, and a selection circuit that simultaneously selects multiple word lines and multiple bit lines, and writes the initialization data simultaneously into a memory cell connected to the selected word lines and bit lines.

### CROSS-REFERENCE TO RELATED APPLICATIONS

The disclosure of Japanese Patent Application No. 2023-139535 filed on Aug. 30, 2023, including the specification, drawings and abstract is incorporated herein by reference in its entirety.

### BACKGROUND

This disclosure relates to a memory device, for example, SRAM (Static Random Access Memory).

There are disclosed techniques listed below.
[Patent Document 1] Japanese Unexamined Patent Application Publication No. 2023-88805

Technologies for initializing the data of memory cells have been developed. Patent Document 1 discloses a technology for initializing the data of memory cells relatively quickly while suppressing an increase in area. The control circuit of the semiconductor device, based on the reset signal being set to a high level, turns off the first transistor, selects multiple word lines, turns off the precharge circuit, turns on the write column switch, and turns off the read column switch. By setting the first bit line to a low level and the second bit line to a high level by the write circuit, multiple memory cells are initialized.

### SUMMARY

The initialization described in Patent Document 1 shortens the initialization time by initializing all memory cell areas at the same time. However, because the data at the time of initialization is fixed inside the SRAM, it can only be initialized to 0 or 1. Also, only all memory cell areas can be initialized. Therefore, there was a problem that it was not possible to initialize all memory cells at once in a memory with an ECC (Error Checking and Correction) memory or an area where important data is held.

Therefore, the purpose of this disclosure is to provide a memory device that initializes all memory cell data by specifying initialization data or a memory device that initializes all memory cell data by partially masking the initialization area.

Other objects and novel features will become apparent from the description of this specification and the accompanying drawings.

According to one embodiment, the memory device initializes any area with any data.

According to the one embodiment, it is possible to provide a memory device that initializes all memory cell data by specifying initialization data or a memory device that initializes all memory cell data by partially masking the initialization area.

### BRIEF DESCRIPTION OF THE DRAWINGS

FIG. 1 is a schematic diagram showing the state of bulk initialization of the memory device.

FIG. 2 is a schematic diagram showing an example of a state in which the Hamming code of the memory device is masked.

FIG. 3 is a schematic diagram showing another example of a state in which the Hamming code of the memory device is masked.

FIG. 4 is a schematic diagram showing a case where the initialization in the word direction of the memory device is restricted.

FIG. 5 is a schematic diagram showing a case where the initialization in the bit direction of the memory device is restricted.

FIG. 6 is a schematic diagram of a circuit of a memory device according to an embodiment.

FIG. 7 is a diagram with an added circuit to lower the voltage level in the word line driver of the memory device according to the embodiment.

FIG. 8 is a timing chart of the memory device according to the embodiment.

FIG. 9 is a block diagram with an added ECC circuit to the memory device according to the embodiment.

### DETAILED DESCRIPTION

For clarity of explanation, the following description and drawings are appropriately omitted and simplified. Each element described in the drawings as a function block for performing various processes can be configured by hardware such as a CPU (Central Processing Unit), memory, and other circuits, and can be realized by software such as a program loaded into memory. Therefore, these function blocks can be realized by hardware, software operating on hardware, or a combination thereof. In the drawings, the same elements are denoted by the same reference numerals, and a repetitive description thereof is omitted as necessary.

### (Description of the Memory Device According to the Embodiment)

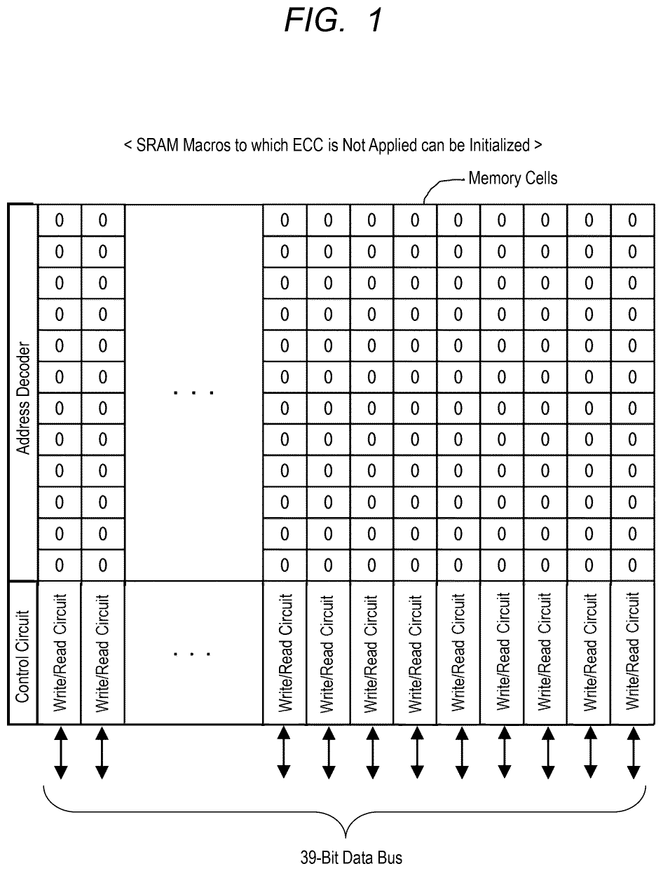

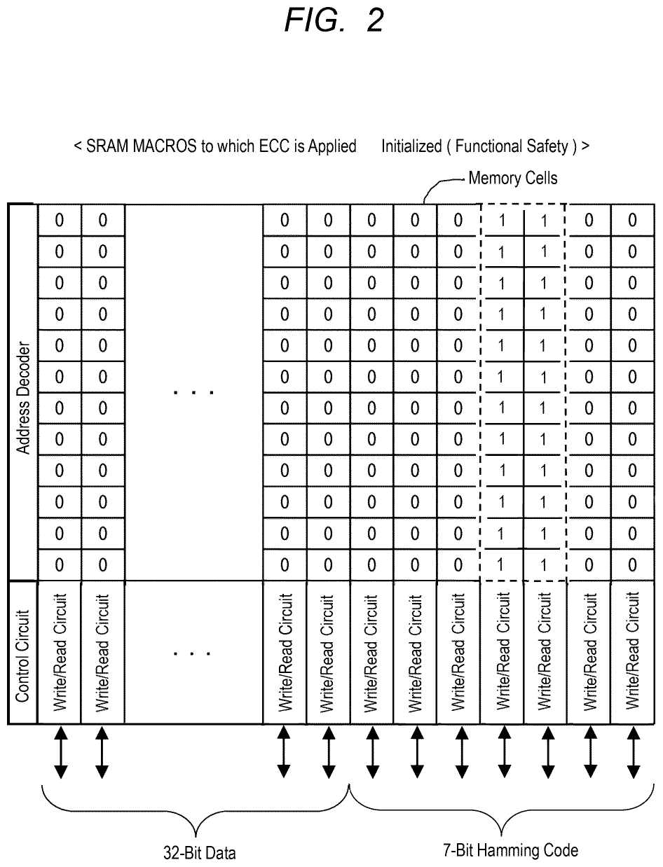

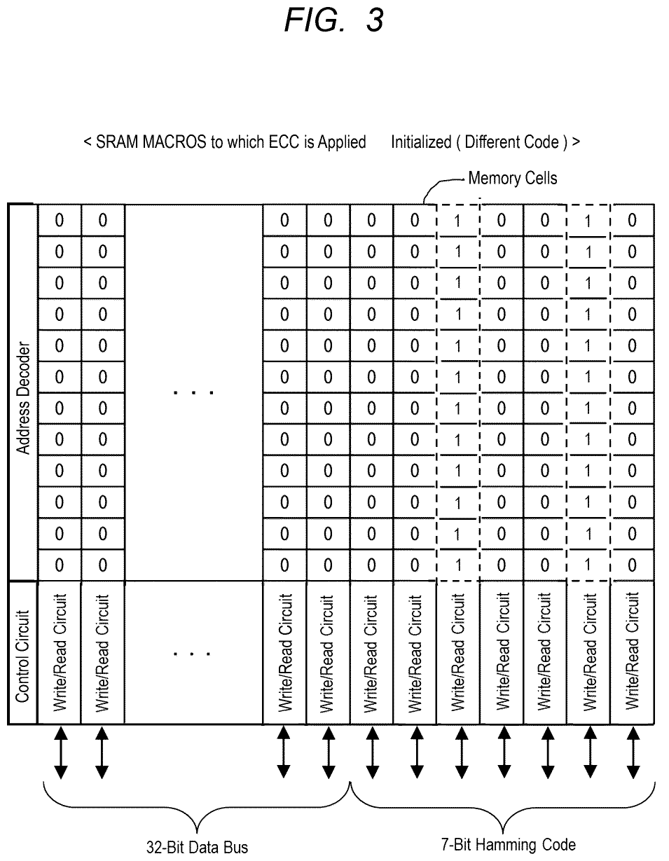

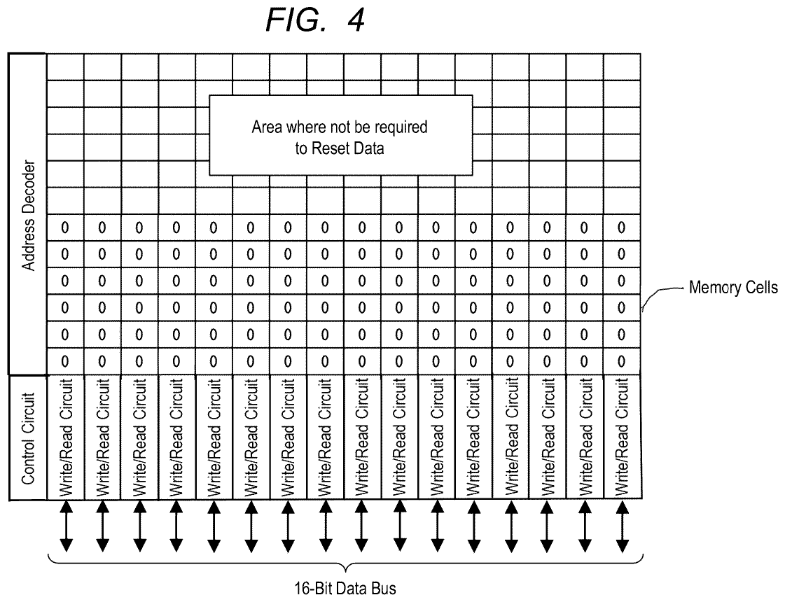

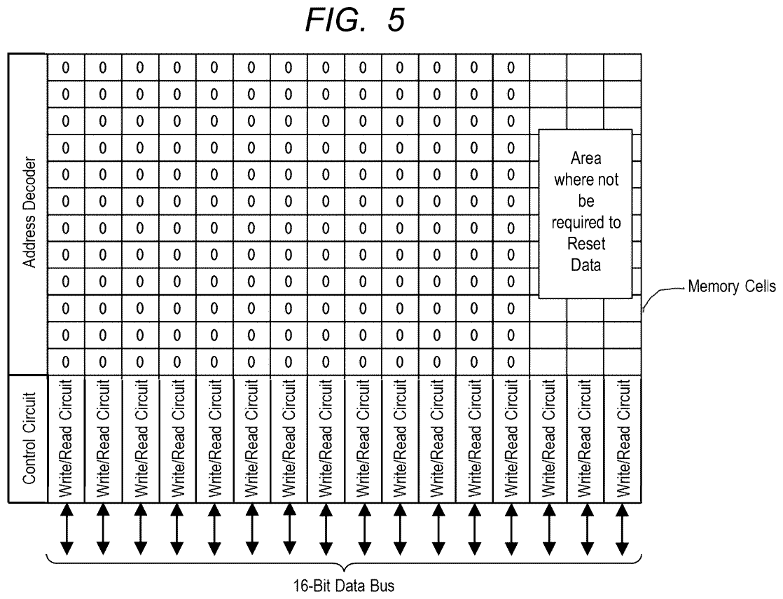

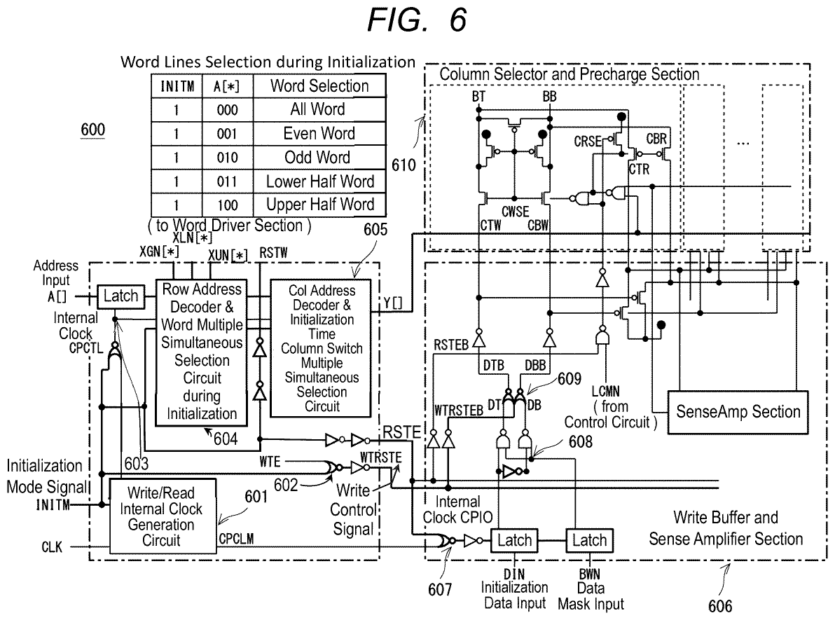

FIG. 1 is a schematic diagram showing the state of bulk initialization of the memory device. FIG. 2 is a schematic diagram showing an example of a state in which the Hamming code of the memory device is masked. FIG. 3 is a schematic diagram showing another example of a state in which the Hamming code of the memory device is masked. FIG. 4 is a schematic diagram showing a case where the initialization in the word direction of the memory device is restricted. FIG. 5 is a schematic diagram showing a case where the initialization in the bit direction of the memory device is restricted. FIG. 6 is a schematic diagram of a circuit of a memory device according to an embodiment. The memory device according to the embodiment will be described with reference to FIGS. 1 to 6. The memory device 600 is, for example, an SRAM (Static Random Access Memory).

As shown in FIG. 1, SRAM macros to which ECC is not applied can be initialized in bulk. The memory area is set to all zeros. On the other hand, it is desirable that SRAM macros to which ECC is applied are not all zeros, as shown in FIGS. 2 and 3, for example. From the viewpoint of functional safety, as shown in FIG. 2, it is desirable to put a value of 1 in the Hamming code of adjacent bit lines. Also, as shown in FIG. 3, it is desirable to put a value of 1 in the Hamming code with a different code.

Also, as shown in FIG. 4, there may be a case where it is desired to restrict the initialization in the word line direction. Furthermore, as shown in FIG. 5, there may be a case where it is desired to restrict the initialization in the bit line direction. The memory device of the present disclosure is a memory device that specifies initialization data of memory cell data and initializes it in bulk, or a memory device that masks a part of the initialization area of the memory cell data and initializes it in bulk, and these states can be realized in bulk.

As shown in FIG. 6, the memory device 600 according to the embodiment includes an initialization control circuit (not shown), a Write/Read internal clock generation circuit 601, a write control circuit 602, an internal clock generation circuit 603, a Row address decoder and word multiple simultaneous selection circuit 604 during initialization, a Col address decoder and column switch multiple simultaneous selection circuit 605 during initialization, an internal clock generation circuit 607, a BitWrite mask circuit 608, and a Write circuit 609.

The initialization control circuit sends an initialization mode signal that transitions the memory device to the initialization mode. The initialization mode is a state in which initialization is performed. Also, the initialization control circuit sends 0 or 1 initialization data to write to the memory device 600. The initialization data is data for initializing the memory device. Also, the initialization control circuit may send an initialization address area mask signal that masks the area to be initialized. Also, the initialization control circuit may send an initialization data mask signal that masks the data to be initialized.

The control circuit 602, the internal clock generation circuit 603, and the internal clock generation circuit 607 are collectively referred to as a control circuit. The internal clock generation circuit 603 receives a clock signal and an initialization mode signal from the Write/Read internal clock generation circuit 601 to generate an internal clock for initialization. The internal clock generation circuit 607 receives a clock signal and an initialization mode signal from the Write/Read internal clock generation circuit 601 to generate an internal clock for initialization. The write control circuit 602 generates a write control signal that enables the Write circuit's enable signal during initialization to enable writing.

The Row address decoder and word multiple simultaneous selection circuit 604 during initialization is also referred to as the word line selection circuit 604. The word line selection circuit 604 has the function of a normal Row address decoder. Furthermore, the word line selection circuit 604 can restrict the initialization in the word line direction by selecting word lines with arbitrary variations by capturing the initialization area information input.

As shown in the table in FIG. 6, for example, when the initialization mode signal INITM is 1 and the address input A is 000, all word lines are selected. When the initialization mode signal is 1 and the address input A is 001, even word lines are selected. When the address input A is 010, odd word lines are selected. When the address input A is 011, the lower half word lines are selected. When the address input A is 100, the upper half word lines are selected. In this way, multiple word lines can be selected simultaneously at initialization.

The Col address decoder and the initialization time column switch multiple simultaneous selection circuit 605, also known as the bit line selection circuit 605. The bit line selection circuit 605 is equipped with the function of a column address decoder. Furthermore, the bit line selection circuit 605 can capture initialization area information input and select a column switch with any variation, thereby limiting the initialization in the bit line direction on a column-by-column basis.

The word line selection circuit 604 and the bit line selection circuit 605 are collectively referred to as a selection circuit. In this way, the selection circuit masks a part of the initialization of the address area based on the initialization address area mask signal input from the initialization control circuit. The word line selection circuit 604 is connected to the word driver section 700. The bit line selection circuit 605 is connected to the column selector and the precharge section 610.

The BitWrite mask circuit 608 has a function to disable data input during normal times and limit input in the bit line direction. Normal times refer to when the memory device 600 is used as a memory device. Furthermore, the BitWrite mask circuit 608 also has a function to disable data input during initialization and limit input in the bit line direction.

The Write circuit 609 has a function to input 0 or 1 data during normal times. Furthermore, the Write circuit 609 has a function to input 0 or 1 data during initialization. The BitWrite mask circuit 608 and the Write circuit 609 are collectively referred to as the IO input circuit. In this way, the IO input circuit masks a part of the IO input of the memory cell according to the initialization data mask signal input from the initialization control circuit.

The internal clock generation circuit 607 and the IO input circuit are collectively referred to as the write buffer and sense amplifier section 606. The write buffer and sense amplifier section 606 are connected to the column selector and the precharge section 610. The column selector and precharge section 610 are equipped with BT (Bit True) lines and BB (Bit Bar) lines connected to the memory cells. During normal times, a high level is applied to the True side and Bar side of the bit line. Initialization is performed by applying a low level to the True side or Bar side of the bit line.

With the above configuration, it is possible to provide a memory device that initializes all memory cell data by specifying initialization data, or a memory device that masks a part of the initialization area of the memory cell data and initializes all of them.

### (Description of the Word Driver Section of the Memory Device According to the Embodiment)

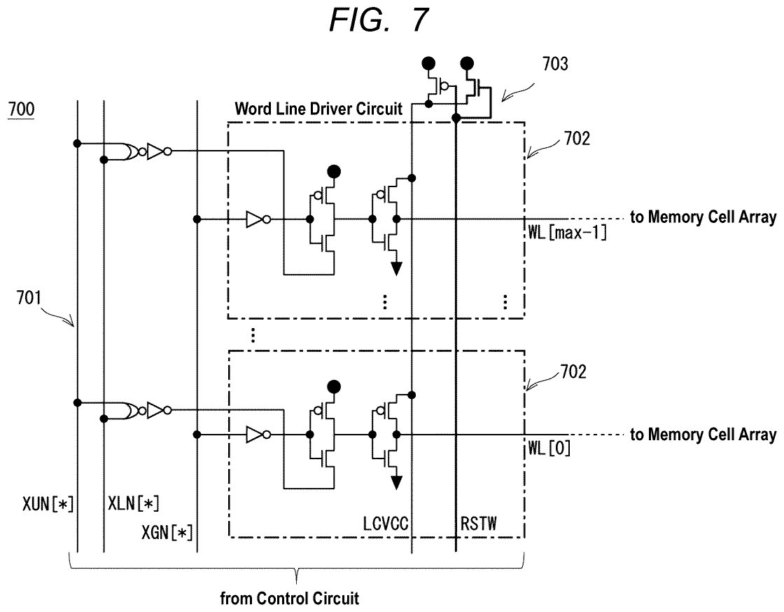

FIG. 7 is a diagram with a circuit added to lower the voltage level of the word line driver of the memory device according to the embodiment. Referring to FIG. 7, the word driver section of the memory device according to the embodiment will be described. The word driver section 700 is a circuit that drives the word line.

As shown in FIG. 7, the word driver section 700 includes a wiring 701 connected to the word line selection circuit 604, a word line driver circuit 702, and a level reduction circuit 703.

The wiring 701 is connected to multiple word line driver circuits 702. The wiring 701 raises multiple word lines in response to a signal generated by the word line selection circuit 604 during initialization.

Multiple word line driver circuits 702 are connected to one level reduction circuit 703. The level reduction circuit 703 is a complementary transistor equipped with an N-channel type transistor and a P-channel type transistor. The level reduction circuit 703 is connected to the gate with a reset write signal, and the output is connected to the power line of the word driver circuit. The level reduction circuit 703 allows a through current to flow during the initialization restriction in the bit line direction, so it turns off the P-channel type transistor and turns on the N-channel type transistor during initialization. Therefore, the level reduction circuit 703 can lower the high level potential of the word line at the time of rising. As a result, the level reduction circuit 703 suppresses the peak current and the charge/discharge current, thereby reducing the power consumption of the memory device 600.

### (Description of the Timing Chart of the Memory Device According to the Embodiment)

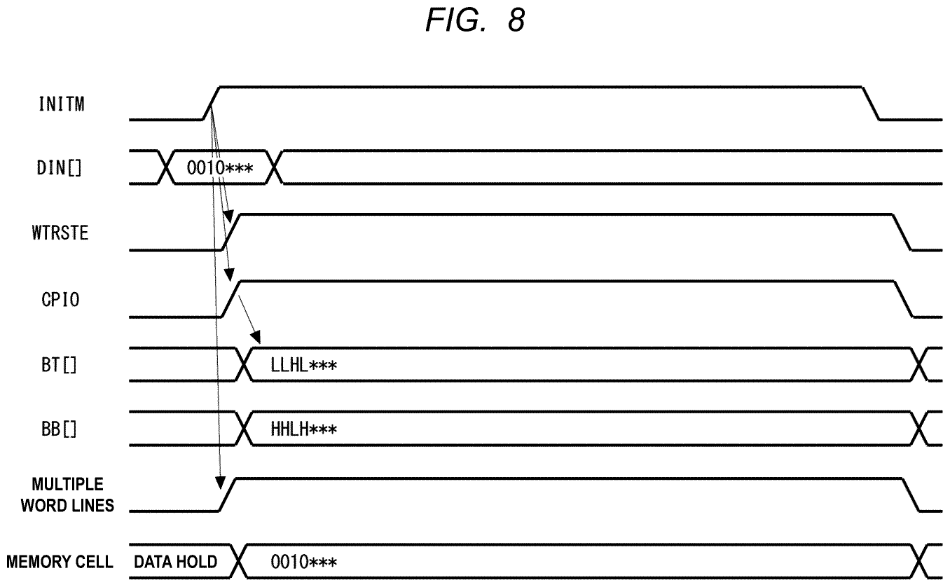

FIG. 8 is a timing chart of the memory device according to the embodiment. Referring to FIGS. 6 and 8, the timing chart of the memory device according to the embodiment will be described.

As shown in FIGS. 6 and 8, INITM is an initialization mode signal. When the initialization mode signal becomes High level, initialization is executed. When the initialization mode signal INITM becomes High, the write control signal WIRSTE of the write control circuit 602 becomes High. Also, when the initialization mode signal INITM becomes High, the internal clock CPIO of the internal clock generation circuit 607 becomes High.

Then, LLHL data is input to the BT (Bit True) line according to the initialization data input DIN (0010). HHLH data is input to the BB (Bit Bar) line according to the initialization data input DIN (0010).

In response to the initialization mode signal, multiple word lines are selected in the High state, and the memory cell inputs (0010) data according to the initialization data input DIN (0010).

With the above configuration, multiple word lines are selected, and the selected initialization data is input to the memory cell.

(Description of the Memory Device with Added ECC (Error Checking and Correction) Circuit According to the Embodiment)

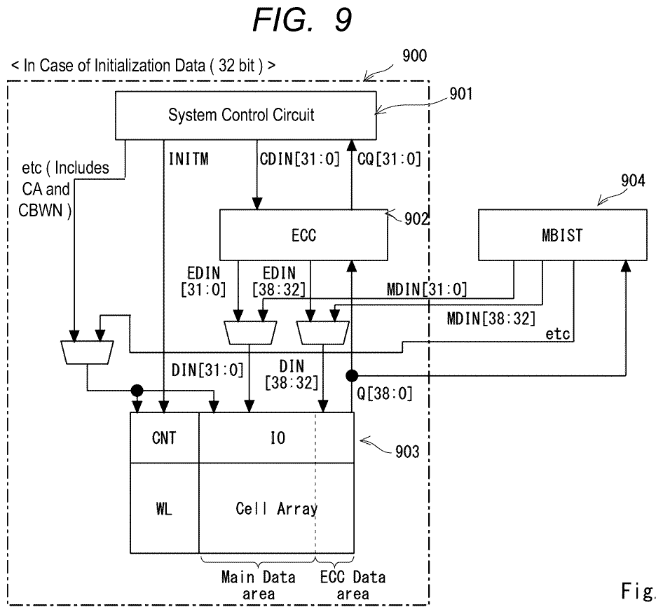

FIG. 9 is a block diagram of the memory device with added ECC circuit according to the embodiment. Referring to FIG. 9, the memory device with added ECC circuit according to the embodiment will be described. The ECC circuit is an error detection/correction circuit.

The memory device 900 with added ECC circuit includes a system control circuit 901, an ECC circuit 902, and a memory device 903.

The MBIST (Memory Built In Self Test) circuit 904 is a test circuit that tests the memory before shipment. For example, it outputs initialization data MDIN during the initialization before shipment of the memory device 900 with added ECC circuit.

The system control circuit 901 includes an initialization control circuit. In the memory test after shipment, the system control circuit 901 outputs the initialization mode signal INITM, initialization data CDIN, initialization address area mask signal CA, and initialization data mask signal CBWN.

The ECC circuit 902 is connected to the system control circuit 901. Also, the ECC circuit is connected to the memory device 903. That is, the ECC circuit 902 is arranged between the system control circuit 901 and the memory device 903. The ECC circuit receives initialization data and transmits error detection/correction code EDIN.

The memory device 903 is, for example, an SRAM macro. The memory device 903 captures initialization data including a Hamming code output from ECC during initialization in the memory test after shipment, and is collectively initialized according to the data DIN.

The initialization flow of the memory device 900 with added ECC circuit is as follows. First, the system control circuit 901 outputs initialization data including a bit designation signal to the ECC circuit. Also, the system control circuit 901 outputs an address signal specifying the initialization area to the memory device 903. Next, the ECC circuit 902 receives the initialization data and generates a Hamming code. Next, the memory device 903 receives the initialization data including the Hamming code from the ECC circuit 902 and receives the initialization area designation address signal from the system control circuit 901. Next, the system control circuit 901 outputs the initialization mode signal to the memory device 903. Finally, the memory device 903 performs initialization processing of the specified area.

With the above configuration, it can cope with initialization with initialization data including a Hamming code due to the addition of the ECC circuit.

Although the invention made by the inventor has been specifically described based on the embodiment, the present invention is not limited to the embodiment already described, and it is needless to say that various modifications can be made without departing from the gist thereof.

What is claimed is:

1. A memory device comprising:
a control circuit configured to receive an initialization mode signal transmitted from an initialization control circuit and to generate an internal clock and a write control signal;
an I/O input circuit configured to apply a low level to the True side or Bar side of a bit line according to initialization data transmitted from the initialization control circuit; and
a selection circuit configured to simultaneously selects a plurality of word lines and a plurality of bit lines, and to write the initialization data simultaneously into a memory cell connected to the selected word lines and bit lines.

2. The memory device according to claim 1, wherein the initialization control circuit generates an initialization address area mask signal that masks the area to be initialized, and the selection circuit masks the initialization of a part of the address area based on the initialization address area mask signal input from the initialization control circuit.

3. The memory device according to claim 1, wherein the initialization control circuit generates an initialization data mask signal that masks the data to be initialized, and the IO input circuit masks a part of the IO input of the memory cell according to the initialization data mask signal input from the initialization control circuit.

4. The memory device according to claim 1, wherein a word driver section connected to the selection circuit lowers the High level potential of the selected multiple word lines.

5. The memory device according to claim 1, further comprising an error detection/correction circuit disposed between the initialization control circuit and the memory device, which captures the initialization mode signal, the initialization data, the initialization data mask signal that masks the data to be initialized, the initialization address area mask signal that masks the area to be initialized, and the error detection/correction code transmitted from the error detection/correction circuit, and initializes the data of the memory cell in a batch.

6. The memory device according to claim 1, wherein the memory device is an SRAM macro.
